(19) United States
(12) Patent Application Publication
(10) Pub. No.: US 2021/0270892 A1
(43) Pub. Date: Sep. 2, 2021

(54) METHOD AND SYSTEM FOR EXTRACTING FAULT FEATURE OF ANALOG CIRCUIT BASED ON OPTIMAL WAVELET BASIS FUNCTION

(71) Applicant: WUHAN UNIVERSITY, Hubei (CN)

(72) Inventors: Yigang HE, Hubei (CN); Chaolong ZHANG, Hubei (CN); Ting YANG, HUBEI (CN); Guolong SHI, Hubei (CN); Liulu HE, Hubei (CN); Yuanxin XIONG, HUBEI (CN); Bolun DU, Hubei (CN); Baoran AN, HUBEI (CN)

(73) Assignee: WUHAN UNIVERSITY, Hubei (CN)

(21) Appl. No.: 17/129,757

(22) Filed: Dec. 21, 2020

(30) Foreign Application Priority Data
Mar. 2, 2020 (CN) 202010134689.2

(51) Int. Cl. G01R 31/316

(52) U.S. Cl. CPC G01R 31/316

(57) ABSTRACT

The disclosure discloses an analog circuit fault feature extraction method and system based on an optimal wavelet basis function, and belongs to the field of electronic circuit engineering and computer vision, and the method comprises the steps of obtaining output signals of an analog circuit during different faults; sequentially applying wavelet transformation methods based on different wavelet basis functions to extract features of output signals; for each feature, calculating the center position of each fault, the distance from each fault data point to the center position, the farthest position of the fault data point and the average position of the fault data points; and determining an optimal wavelet basis function for analog circuit fault feature extraction according to a score discriminating method.

### CROSS-REFERENCE TO RELATED APPLICATION

This application claims the priority benefit of China application serial no. 202010134689.2, filed on Mar. 2, 2020. The entirety of the above-mentioned patent application is hereby incorporated by reference herein and made a part of this specification.

### BACKGROUND

### Technical Field

The disclosure belongs to the field of electronic circuit engineering and computer vision, and more specifically, relates to a method and system for extracting fault features of analog circuit based on an optimal wavelet basis function.

### Description of Related Art

Analog circuits are commonly applied to industrial electronic equipment, agricultural electronic equipment, avionics and household electronic equipment. The failure of analog circuits will cause performance degradation, slow response, and malfunction of the electronic equipment. The accurate fault diagnosis of the analog circuit helps to maintain the circuit in time, thus ensuring the normal operation of the electronic equipment.

The fault diagnosis of analog circuit can be classified into two parts, feature extraction and classifier recognition. Specifically, feature extraction is the basis of fault diagnosis. Extracting features that are easy to classify is essential for accurate fault diagnosis of analog circuits. The current commonly adopted fault feature extraction method is the wavelet transform method. However, it is required that the wavelet basis function be set in the wavelet transform method. Typically, the wavelet basis function is selected by using an empirical method, and it is difficult to determine the optimal wavelet basis function, which reduces the efficiency and accuracy of analog circuit fault diagnosis.

### SUMMARY

### Technical Problem

In view of the above defects or requirements for improvement of related art, the disclosure provides a method and system for extracting fault features of analog circuits based on optimal wavelet basis functions, thereby solving the difficulty in determining the optimal wavelet basis function in the wavelet transform method currently adopted for extracting fault features.

In order to achieve the above purpose, according to one aspect of the disclosure, a method for extracting fault features of an analog circuit based on an optimal wavelet basis function is provided, including:

The output signal of the analog circuit during different faults is obtained;

The wavelet transform method based on different wavelet basis functions is applied in sequence to extract the feature of each output signal;

For the features extracted based on each wavelet basis function, the center position of each fault and the distance between each fault data point and the center position are calculated, the farthest position of the fault data point and the average position of the fault data point are also calculated;

According to the center position of each fault, the distance between each fault data point and the center position, the farthest position of the fault data point and the average position of the fault data point, the score of features extracted based on each wavelet basis function is obtained, thereby determining the optimal wavelet basis function for extracting fault features of analog circuit according to the score.

Preferably, the center position of each fault is obtained based on

$${Mean}_{j , k} = \frac{1}{N} {\sum }_{i = 1}^{N} {P}_{j , k , i} ,$$

the distance between each fault data point and the center position is obtained based on O_{j,k,i}=Distance(Mean_{j,k}, P_{j,k,i}), the farthest position of the fault data point is obtained based on max O_{j,k}=arg max{O_{j,k,i}}, and the average position of the fault data point is obtained based on

$${meanO}_{j , k} = \frac{1}{N} {\sum }_{i = 1}^{N} {O}_{j , k , i} ,$$

wherein j=1 . . . J, J is the number of wavelet basis functions; k=1 . . . K, K is the number of faults; i=1 . . . N, N is the number of data points for a single fault; P_{j,k,i} is the coordinate position of the i-th data point of the k-th fault in the feature extracted based on the j-th wavelet basis function, Distance is the Euclidean distance calculation function, and O_{j,k,i} is the distance between the i-th data point P_{j,k,i} of the k-th fault in the feature extracted based on the j-th wavelet basis function and the center position Mean_{j,k}.

Preferably, the score of the feature extracted based on the j-th wavelet basis function is obtained based on

$${Score}_{j} = {\sum }_{m = 1}^{C ( K , 2 )} {Judge}_{j , m} ,$$

wherein m=1 . . . C(K, 2), which is the m-th combination of two faults among the K types of faults, and Judge_{j,m} is the score of m-th combination of two faults, and

$${Judge}_{j , m} = \{ \begin{matrix}1 & \begin{matrix}Distance ( {Mean}_{j , {k}_{1}} , {Mean}_{j , {k}_{2}} ) \geq \\ {maxO}_{j , {k}_{1}} + {maxO}_{j , {k}_{2}}\end{matrix} \\ \begin{matrix}Distance ( {Mean}_{j , {k}_{1}} , {Mean}_{j , {k}_{2}} ) / \\ ( {maxO}_{j , {k}_{1}} + {maxO}_{j , {k}_{2}} )\end{matrix} & \begin{matrix}Distance ( {Mean}_{j , {k}_{1}} , {Mean}_{j , {k}_{2}} ) < \\ {maxO}_{j , {k}_{1}} + {maxO}_{j , {k}_{2}}\end{matrix}\end{matrix} ,$$

wherein k₁, k₂ indicate two different faults.

Preferably, the wavelet basis function with the highest score is determined based on Scoreₜ=arg max {Scoreⱼ}. If there is only one wavelet basis function with the highest score, the wavelet basis function with the highest score is used as the optimal wavelet basis function for extracting fault features of analog circuit.

If there are S types of wavelet basis functions satisfying the highest score, the s-th type of wavelet basis function among the S types of wavelet basis functions that satisfy

$${meanO}_{j , s} = arg min \{ {\sum }_{j = 1}^{J} {meanO}_{j , k} \}$$

is taken as the optimal wavelet basis function for extracting the fault features of analog circuit.

Preferably, the number of wavelet basis functions is equal to the number of features; the coordinate position of the i-th data point of the k-th fault in the feature extracted based on the j-th wavelet basis function is the value of the i-th data point of the k-th faults in the feature extracted based on the j-th wavelet basis function.

According to another aspect of the disclosure, a system for extracting fault features of an analog circuit based on an optimal wavelet basis function is provided, which includes:

A data acquisition module is configured to acquire the output signal of the analog circuit during different faults;

A feature extraction module is configured to sequentially apply wavelet transform method based on different wavelet basis functions to extract the feature of each output signal;

A calculation module is configured to calculate, for the feature extracted based on each wavelet basis function, the center position of each fault, the distance between each fault data point and the center position, the farthest position of the fault data point and the average position of the fault data point;

A feature score discriminating module is configured to obtain the score of the feature extracted based on each wavelet basis function according to the center position of each fault, the distance between each fault data point and the center position, the farthest position of the fault data point and the average position of the fault data point;

A wavelet basis function determining module is configured to determine the optimal wavelet basis function for extracting fault features of an analog circuit according to the score.

Preferably, the calculation module is configured to obtain the center position of each fault based on

$${Mean}_{j , k} = \frac{1}{N} {\sum }_{i = 1}^{N} {P}_{j , k , i} ,$$

obtain the distance between each fault data point and the center position based on O_{j,k,i}=Distance(Mean_{j,k}, P_{j,k,i}), obtain the farthest position of the fault data point based on max O_{j,k}=arg max{O_{j,k,i}}, and obtain the average position of the fault data point based on

$${meanO}_{j , k} = \frac{1}{N} {\sum }_{i = 1}^{N} {O}_{j , k , i} ,$$

wherein j=1 . . . J, J is the number of wavelet basis functions; k=1 . . . K, K is the number of faults; i=1 . . . N, N is the number of data points for a single fault; P_{j,k,i} is the coordinate position of the i-th data point of the k-th fault in the feature extracted based on the j-th wavelet basis function, Distance is the Euclidean distance calculation function, and O_{j,k,i} is the distance between the i-th data point P_{j,k,i} of the k-th fault in the feature extracted based on the j-th wavelet basis function and the center position Mean_{j,k}.

Preferably, the feature score discriminating module is configured to obtain the score of the feature extracted based on the j-th wavelet basis function based on

$${Score}_{j} = {\sum }_{m = 1}^{C ( K , 2 )} {Judge}_{j , m} ,$$

wherein m=1 . . . C(K, 2), which is the m-th combination of two faults among the K types of faults, and Judge_{j,m} is the score of m-th combination of two faults, and

$${Judge}_{j , m} = \{ \begin{matrix}1 & \begin{matrix}Distance ( {Mean}_{j , {k}_{1}} , {Mean}_{j , {k}_{2}} ) \geq \\ {maxO}_{j , {k}_{1}} + {maxO}_{j , {k}_{2}}\end{matrix} \\ \begin{matrix}Distance ( {Mean}_{j , {k}_{1}} , {Mean}_{j , {k}_{2}} ) / \\ ( {maxO}_{j , {k}_{1}} + {maxO}_{j , {k}_{2}} )\end{matrix} & \begin{matrix}Distance ( {Mean}_{j , {k}_{1}} , {Mean}_{j , {k}_{2}} ) < \\ {maxO}_{j , {k}_{1}} + {maxO}_{j , {k}_{2}}\end{matrix}\end{matrix} ,$$

wherein k₁, k₂ indicate two different faults.

Preferably, the wavelet basis function determining module is configured to determine the wavelet basis function with the highest score based on Scoreᵢ=arg max{Scoreⱼ}. If there is only one wavelet basis function satisfying the highest score, the wavelet basis function satisfying the highest score is used as the optimal wavelet basis function for extracting fault features of analog circuit.

If there are S types of wavelet basis functions satisfying the highest score, the s-th type of wavelet basis function among the S types of wavelet basis functions that satisfy

$${meanO}_{j , s} = arg min \{ {\sum }_{j = 1}^{J} {meanO}_{j , k} \}$$

is taken as the optimal wavelet basis function for extracting the fault features of analog circuit.

Preferably, the number of wavelet basis functions is equal to the number of features; the coordinate position of the i-th data point of the k-th fault in the feature extracted based on the j-th wavelet basis function is the value of the i-th data point of the k-th faults in the feature extracted based on the j-th wavelet basis function.

According to another aspect of the disclosure, a computer-readable storage medium having program instructions stored therein is provided. When the program instructions are executed by a processor, any one of the methods for extracting fault features of analog circuit based on an optimal wavelet basis function is realized.

In general, compared with the related art, the above technical solutions conceived by the disclosure can achieve the following advantageous effects:

The method for extracting fault features of analog circuit based on optimal wavelet basis functions provided by the disclosure is superior to the conventional method of using empirical methods to set wavelet basis functions to extract fault features of analog circuits, and can effectively find the optimal wavelet basis functions, and thus can effectively improve the efficiency and accuracy for diagnosing faults of analog circuits.

### BRIEF DESCRIPTION OF THE DRAWINGS

FIG. 1 is a schematic flowchart of a method for extracting fault features of an analog circuit based on an optimal wavelet basis function according to an embodiment of the disclosure.

FIG. 2 is a schematic diagram showing the principle of a Sallen-Key bandpass filter according to an embodiment of the disclosure.

FIG. 3 is a schematic structural diagram of a system for extracting fault features of an analog circuit based on an optimal wavelet basis function according to an embodiment of the disclosure.

### DESCRIPTION OF THE EMBODIMENTS

In order to make the purpose, technical solutions, and advantages of the disclosure clearer, the disclosure is further described in detail below with reference to the accompanying drawings and embodiments. It should be understood that the specific embodiments described here are only used to explain the disclosure, but not to limit the disclosure. In addition, the technical features involved in the various embodiments of the disclosure described below can be combined with each other as long as they do not conflict with each other.

The disclosure provides a method for extracting fault features of an analog circuit based on an optimal wavelet basis function. First, the output signal of the analog circuit during different faults is obtained. Then, the wavelet transform method based on different wavelet basis functions is applied in sequence to extract the feature of each output signal. For each of the features, the center position of each fault and the distance between each fault data point and the center position are calculated, the farthest position of the fault data point and the average position of the fault data point are also calculated. The optimal wavelet basis function for extracting fault features of an analog circuit is determined according to the score discriminating method. The features extracted based on the optimal wavelet basis function can achieve a higher accuracy rate for fault diagnosis.

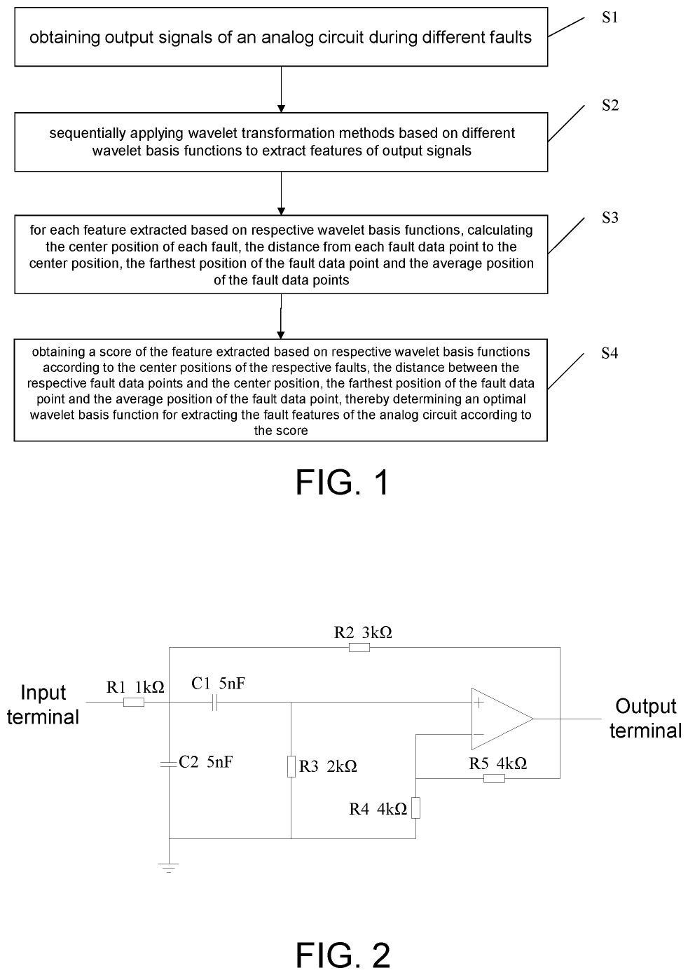

As shown in FIG. 1, which is a schematic flowchart of a method for extracting fault features of an analog circuit based on an optimal wavelet basis function according to an embodiment of the disclosure, including the following steps:

S1: The output signal of the analog circuit during different faults is obtained.

In the embodiment of the disclosure, the output signal may be a voltage signal sampled at the output terminal of the analog circuit.

S2: The wavelet transform method based on different wavelet basis functions is applied in sequence to extract the feature of each output signal.

In the embodiment of the disclosure, different wavelet basis functions are sequentially adopted to perform wavelet transformation on each output signal, and the generated scale coefficients are used as features. The calculation method is as follows:

It is set that f(x) is the collected output signal, in the wavelet transformation, it is set that {Vₖ}_{k∈Z} is the orthogonal multi-resolution analysis, {Wₖ}_{k∈Z} is the correspondingly decomposed wavelet space, wherein f(x) in the orthogonal projection on Vₖ is expressed as:

$${P}_{{V}_{k}} f = {P}_{{V}_{k + 1}} f + {P}_{{W}_{k + 1}} f = {\sum }_{i ∈ Z}^{ } {c}_{k + 1}^{i} {ϕ}_{k + 1 , i} + {\sum }_{i ∈ Z}^{ } {d}_{k + 1}^{i} {ψ}_{k + 1 , i}$$

Specifically, P_{V}_{ₖ₊₁}f and P_{W}_{ₖ₊₁}f respectively denote the projection of f(x) on Vₖ₊₁ and Wₖ₊₁, k and i are discretization parameters, ϕ_{k+1,i} and ψ_{k+1,i} are the scale function and wavelet function of f(x) at a resolution of 2^{k+1}, respectively. cₖ₊₁ⁱ and dₖ₊₁ⁱ are the scale coefficients and wavelet coefficients of f(x) at a resolution of 2^{k+1}. cₖ₊₁ and dₖ₊₁ are the approximation and details of f(x) at a resolution of 2^{k+1}, that is, the low-frequency component and high-frequency component of the signal f(x), and Z represents a real number.

S3: For the features extracted based on each wavelet basis function, the center position of each fault and the distance between each fault data point and the center position are calculated, the farthest position of the fault data point and the average position of the fault data point are also calculated.

In the embodiment of the disclosure, the calculation formula for the center position of each fault is:

$${Mean}_{j , k} = \frac{1}{N} {\sum }_{i = 1}^{N} {P}_{j , k , i} \qquad ( 1 )$$

Specifically, j=1 . . . J, J is the number of wavelet basis functions; k=1 . . . K, K is the number of faults; i=1 . . . N, N is the number of data points for a single fault; P_{j,k,i} is the coordinate position of the i-th data point of the k-th fault in the feature extracted based on the j-th wavelet basis function, that is, the value of the i-th data point of the k-th faults in the feature extracted based on the j-th wavelet basis function.

Specifically, one type of wavelet basis function can be used to extract one type of feature, and one type of feature can be used to identify K faults. Therefore, wavelet basis functions and features have a one-to-one correspondence, and the number of wavelet basis functions is equal to the number of features.

The calculation of the distance between each fault data point and the center position is to calculate the Euclidean distance between each fault data point and the fault center position:

O_{j,k,i}=Distance(Mean_{j,k},P_{j,k,i}) (2)

Specifically, Distance is the Euclidean distance calculation function, and O_{j,k,i} obtained through calculation is the distance between the i-th data point of the k-th fault in the feature extracted based on the j-th wavelet basis function and the center position.

The farthest distance of the fault data point is:

max O_{j,k}=arg max{O_{j,k,i}} (3)

The average distance of fault data points is:

$${meanO}_{j , k} = \frac{1}{N} {\sum }_{i = 1}^{N} {O}_{j , k , i} \qquad ( 4 )$$

S4: The optimal wavelet basis function for extracting fault features of an analog circuit is determined according to the score discriminating method.

In the embodiment of the disclosure, the discriminating process of the score discriminating method is as follows:

The score Scoreⱼ corresponding to the j-th wavelet basis function is:

$${Score}_{j} = {\sum }_{m = 1}^{C ( K , 2 )} {Judge}_{j , m} \qquad ( 5 )$$

Specifically, m=1 . . . C(K, 2), which is the m-th combination of two faults among the K types of faults, and Judge_{j,m} is the score of m-th combination of two faults, and the calculation method is as follows:

$${Judge}_{j , m} = \{ \begin{matrix}1 & \begin{matrix}Distance ( {Mean}_{j , {k}_{1}} , {Mean}_{j , {k}_{2}} ) \geq \\ {maxO}_{j , {k}_{1}} + {maxO}_{j , {k}_{2}}\end{matrix} \\ \begin{matrix}Distance ( {Mean}_{j , {k}_{1}} , {Mean}_{j , {k}_{2}} ) / \\ ( {maxO}_{j , {k}_{1}} + {maxO}_{j , {k}_{2}} )\end{matrix} & \begin{matrix}Distance ( {Mean}_{j , {k}_{1}} , {Mean}_{j , {k}_{2}} ) < \\ {maxO}_{j , {k}_{1}} + {maxO}_{j , {k}_{2}}\end{matrix}\end{matrix} . \qquad ( 6 )$$

The basis for choosing the t-th wavelet basis function is:

Scoreₜ=arg max{Scoreⱼ} (7)

If there are S types of wavelet basis functions that satisfy formula (7), then the s-th type of wavelet basis function in formula (8) is satisfied among S types of wavelet basis functions:

$${meanO}_{j , s} = arg min \{ {\sum }_{j = 1}^{J} {meanO}_{j , k} \} \qquad ( 8 )$$

In the following, an example of fault diagnosis of an analog circuit is adopted to illustrate the method for extracting fault features of an analog circuit based on the optimal wavelet basis function in the disclosure.

FIG. 2 shows a Sallen-Key bandpass filter, the nominal value of each component is marked on the figure. Take this circuit as an example to show the whole process of the method for extracting fault features of analog circuits based on optimal wavelet basis functions provided in the disclosure. The excitation source adopts a pulse wave with a duration of 10 us and an amplitude of 5 v. The fault time domain response signal is obtained by sampling at the output of the circuit. The tolerance range of resistance and capacitance are set to 5% and 10% respectively. A total of 8 types of faults, including R2↑, R2↓, R3↑, R3↓, C1↑, C1↓, C2↑ and C2↓, are selected, wherein ↑ and ↓ respectively denote that the fault value is higher or lower than the nominal value. Table 1 shows the type of faults, nominal values and fault values of circuit components.

TABLE 1
Fault code, type of fault, nominal value and fault value

| | | |
|---|---|---|
| type of fault | nominal value | fault value |

| | | | | |
|---|---|---|---|---|
| R2↑ | 3 | kΩ | 3.75 | kΩ |
| R2↓ | 3 | kΩ | 2.25 | kΩ |
| R3↑ | 2 | kΩ | 2.5 | kΩ |
| R3↓ | 2 | kΩ | 1.5 | kΩ |
| C1↑ | 5 | nF | 6.25 | nF |
| C1↓ | 5 | nF | 3.75 | nF |
| C2↑ | 5 | nF | 6.25 | nF |
| C2↓ | 5 | nF | 3.75 | nF |

200 data for each type of fault are collected and the data are divided into two parts. The first half of 200 data utilizes the same support vector machine to establish a fault diagnosis model, and the second half of 200 data are adopted to calculate the accuracy rate of fault diagnosis, so as to test the advantages and disadvantages of the optimal wavelet basis function for extracting fault features of analog circuit provided in the disclosure. The wavelet transform method that is applied utilizes Haar, Daubechies, Coiflets, Fejer-Korovkin filters, and Biorthogonal respectively as wavelet basis functions to extract features respectively. The score of each feature extracted is calculated by using the method provided in the disclosure. The result is shown in Table 2. Specifically, the feature extracted by using the wavelet transform method based on Fejer-Korovkin filters as the wavelet basis function satisfying the highest score, which is 20.6542, and the corresponding accuracy rate of fault diagnosis is also the highest, which is 100%. The above example illustrates that the optimal wavelet basis function provided in the disclosure has inventiveness and novelty for use in the method of extracting fault features of analog circuits.

TABLE 2
Diagnosis result of each fault

| | | Accuracy rate of |
|---|---|---|
| Wavelet basis function | Score | fault diagnosis |
| Haar | 19.7624 | 99.5% |
| Daubechies | 18.5062 | 88.5% |
| Coiflets | 20.0406 | 99.75% |
| Fejer-Korovkin filters | 20.6542 | 100% |
| Biorthogonal | 19.4994 | 99.25% |

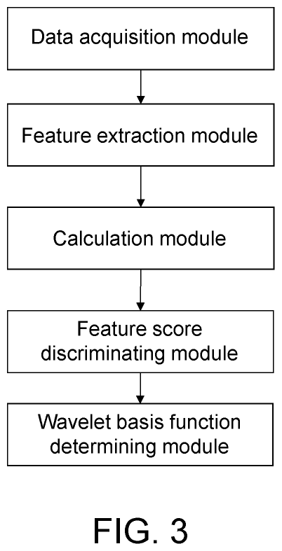

FIG. 3 is a schematic structural diagram of a system for extracting fault features of an analog circuit based on an optimal wavelet basis function according to an embodiment of the disclosure, wherein the system includes:

A data acquisition module is configured to acquire the output signal of the analog circuit during different faults;

The feature extraction module is configured to sequentially apply wavelet transform method based on different wavelet basis functions to extract the feature of each output signal;

A calculation module is configured to calculate, for the feature extracted based on each wavelet basis function, the center position of each fault, the distance between each fault data point and the center position, the farthest position of the fault data point and the average position of the fault data point;

A feature score discriminating module is configured to obtain the score of the feature extracted based on each wavelet basis function according to the center position of each fault, the distance between each fault data point and the center position, the farthest position of the fault data point and the average position of the fault data point;

A wavelet basis function determining module is configured to determine the optimal wavelet basis function for extracting fault features of an analog circuit according to the score.

In the embodiment of the disclosure, the calculation module is configured to obtain the center position of each fault based on

$${Mean}_{j , k} = \frac{1}{N} {\sum }_{i = 1}^{N} {P}_{j , k , l} ,$$

obtain the distance between each fault data point and the center position based on O_{j,k,i}=Distance(Mean_{j,k}, P_{j,k,i}), obtain the farthest position of the fault data point based on max O_{j,k}=arg max{O_{j,k,i}}, and obtain the average position of the fault data point based on

$$m e a n {O}_{j , k} = \frac{1}{N} {\sum }_{i = 1}^{N} {O}_{j , k , i} ,$$

wherein j=1 . . . J, J is the number of wavelet basis functions; k=1 . . . K, K is the number of faults; i=1 . . . N, N is the number of data points for a single fault; P_{j,k,i} is the coordinate position of the i-th data point of the k-th fault in the feature extracted based on the j-th wavelet basis function, Distance is the Euclidean distance calculation function, and O_{j,k,i} is the distance between the i-th data point P_{j,k,i} of the k-th fault in the feature extracted based on the j-th wavelet basis function and the center position Mean_{j,k}.

In the embodiment of the disclosure, the feature score discriminating module is configured to obtain the score of the feature extracted based on the j-th wavelet basis function based on

$${Score}_{j} = {\sum }_{m = 1}^{C ( K , 2 )} {Judge}_{j , m} ,$$

wherein m=1 . . . C(K, 2), which is the m-th combination of two faults among the K types of faults, and Judge_{j,m} is the score of m-th combination of two faults, and

$${Judge}_{j , m} = \\ \{ \begin{matrix}1 & Distance ( {Mean}_{j , {k}_{1}} , {Mean}_{j , {k}_{2}} ) \geq max {O}_{j , {k}_{1}} + max {O}_{j , {k}_{2}} \\ Distance ( {Mean}_{j , {k}_{1}} , {Mean}_{j , {k}_{2}} ) / max {O}_{j , {k}_{1}} + max {O}_{j , {k}_{2}} & Distance ( {Mean}_{j , {k}_{1}} , {Mean}_{j , {k}_{2}} ) < max {O}_{j , {k}_{1}} + max {O}_{j , {k}_{2}}\end{matrix} ,$$

wherein k₁, k₂ indicate two different faults.

In the embodiment of the disclosure, the wavelet basis function determining module is configured to determine the wavelet basis function satisfying the highest score based on Scoreₜ=arg max{Scoreⱼ}. If there is only one wavelet basis function satisfying the highest score, the wavelet basis function satisfying the highest score is used as the optimal wavelet basis function for extracting fault features of analog circuit.

If there are S types of wavelet basis functions satisfying the highest score, the s-th type of wavelet basis function among the S types of wavelet basis functions that satisfy

$$mean {O}_{j , s} = arg min \{ {\sum }_{j = 1}^{J} m e a n {O}_{j , k} \}$$

is taken as the optimal wavelet basis function for extracting the fault features of analog circuit.

In the embodiment of the disclosure, the number of wavelet basis functions is equal to the number of features; the coordinate position of the i-th data point of the k-th fault in the feature extracted based on the j-th wavelet basis function is the value of the i-th data point of the k-th faults in the feature extracted based on the j-th wavelet basis function.

For the specific implementation of each module, reference may be made to the description of the foregoing embodiment of method, and no repetition will be incorporated in the following embodiment.

Another embodiment of the disclosure provides a computer-readable storage medium in which program instructions are stored. When the program instructions are executed by a processor, the method for extracting fault features of analog circuit based on an optimal wavelet basis function is realized.

It should be pointed out that depending on the needs of implementation, each step/component described in this disclosure can be split into more steps/components. Alternatively, two or more steps/components or part of steps/components can be operated and combined into new ones to achieve the purpose of the disclosure.

The above method in the disclosure can be implemented in hardware, firmware, or implemented as software or computer code that can be stored in a recording medium (such as CD ROM, RAM, floppy disk, hard disk, or magneto-optical disk), or implemented as computer code that can be downloaded through the Internet and is originally stored in the remote recording medium or non-transitory machine-readable medium and will be stored in the local recording medium. As such, the method described here can be processed by software that is stored in a general-purpose computer or a specific-purpose processor or programmable recording medium or recording medium for specific hardware (such as ASIC or FPGA). It can be understood that a computer, a processor, a microprocessor controller or a programmable hardware includes a storage element (for example, RAM, ROM, flash memory, etc.) that can store or receive software or computer code. When the software or the computer code is accessed and executed by a computer, processor, or hardware, the processing method described here is implemented. In addition, when a general-purpose computer accesses the code for implementing the processing shown here, the execution of the code converts the general-purpose computer into a specific-purpose computer for implementing the processing described here.

Those skilled in the art can easily understand that the above descriptions are only preferred embodiments of the present disclosure and are not intended to limit the present disclosure. Any modification, equivalent replacement and improvement, etc. made within the spirit and principle of the disclosure should fall within the protection scope of the present disclosure.

What is claimed is:

1. A method for extracting fault features of an analog circuit based on an optimal wavelet basis function, comprising:
obtaining output signals of the analog circuit during different faults;
applying a wavelet transform method in sequence based on different wavelet basis functions to extract a feature of each of the output signals;
for the features extracted based on each of the wavelet basis functions, calculating a center position of each fault and a distance between each fault data point and the center, a farthest position of the fault data point and an average position of the fault data point;
obtaining a score of the feature extracted based on respective wavelet basis functions according to the center positions of the respective faults, the distance between the respective fault data points and the center position, the farthest position of the fault data point and the average position of the fault data point, thereby determining an optimal wavelet basis function for extracting the fault features of the analog circuit according to the score.

2. The method according to claim 1, wherein the center positions of respective faults are obtained based on
$${Mean}_{j , k} = \frac{1}{N} {\sum }_{i = 1}^{N} {P}_{j , k , i} ,$$
the distance between each of the fault data points and the center position is obtained based on O_{j,k,i}=Distance(Mean_{j,k}, P_{j,k,i}), the farthest position of the fault data point is obtained based on max O_{j,k}=arg max{O_{j,k,i}}, and the average position of the fault data point is obtained based on
$$m e a n {O}_{j , k} = \frac{1}{N} {\sum }_{i = 1}^{N} {O}_{j , k , i} ,$$
wherein j=1 . . . J, J is the number of the wavelet basis functions; k=1 . . . K, K is the number of the faults; i=1 . . . N, N is the number of the data points for a single fault; P_{j,k,i} is a coordinate position of the i-th data point of the k-th fault in the feature extracted based on the j-th wavelet basis function, Distance is an Euclidean distance calculation function, and O_{j,k,i} is a distance between the i-th data point P_{j,k,i} of the k-th fault in the feature extracted based on the j-th wavelet basis function and the center position

3. The method according to claim 2, wherein the score of the feature extracted based on the j-th wavelet basis function is obtained based on
$${Score}_{j} = {\sum }_{m = 1}^{C ( K , 2 )} {Judge}_{j , m} ,$$
wherein m=1 . . . C(K, 2), which is the m-th combination of two faults among the K types of faults, and Judge_{j,m} is a score of m-th combination of two faults, and
$${Judge}_{j , m} = \\ \{ \begin{matrix}1 & Distance ( {Mean}_{j , {k}_{1}} , {Mean}_{j , {k}_{2}} ) \geq max {O}_{j , {k}_{1}} + max {O}_{j , {k}_{2}} \\ Distance ( {Mean}_{j , {k}_{1}} , {Mean}_{j , {k}_{2}} ) / max {O}_{j , {k}_{1}} + max {O}_{j , {k}_{2}} & Distance ( {Mean}_{j , {k}_{1}} , {Mean}_{j , {k}_{2}} ) < max {O}_{j , {k}_{1}} + max {O}_{j , {k}_{2}}\end{matrix} ,$$
wherein k₁, k₂ indicate two different faults.

4. The method according to claim 3, wherein the wavelet basis function with the highest score is determined based on Scoreₜ=arg max{Scoreⱼ}, if there is only one wavelet basis function with the highest score, the wavelet basis function with the highest score is used as the optimal wavelet basis function for extracting the fault features of the analog circuit;
if there are S types of wavelet basis functions satisfying the highest score, the s-th type of wavelet basis function among the S types of wavelet basis functions that satisfy
$$ean {O}_{j , s} = argmin \{ {\sum }_{j = 1}^{J} {meanO}_{j , k} \}$$
is taken as the optimal wavelet basis function for extracting the fault features of the analog circuit.

5. The method according to claim 2, wherein the number of the wavelet basis functions is equal to the number of the features; the coordinate position of the i-th data point of the k-th fault in the feature extracted based on the j-th wavelet basis function is the value of the i-th data point of the k-th faults in the feature extracted based on the j-th wavelet basis function.

6. The method according to claim 3, wherein the number of the wavelet basis functions is equal to the number of the features; the coordinate position of the i-th data point of the k-th fault in the feature extracted based on the j-th wavelet basis function is the value of the i-th data point of the k-th faults in the feature extracted based on the j-th wavelet basis function.

7. The method according to claim 4, wherein the number of the wavelet basis functions is equal to the number of the features; the coordinate position of the i-th data point of the k-th fault in the feature extracted based on the j-th wavelet basis function is the value of the i-th data point of the k-th faults in the feature extracted based on the j-th wavelet basis function.

8. A system for extracting fault features of an analog circuit based on an optimal wavelet basis function, comprising:
a data acquisition module configured to acquire an output signal of the analog circuit during different faults;
a feature extraction module configured to sequentially apply a wavelet transform method based on different wavelet basis functions to extract a feature of each of the output signals;
a calculation module configured to calculate, for the features extracted based on the respective wavelet basis functions, a center position of each of the faults, a distance between each fault data point and the center position, a farthest position of the fault data point and an average position of the fault data point;
a feature score discriminating module configured to obtaining a score of the feature extracted based on respective wavelet basis functions according to the center positions of the respective faults, the distance between the respective fault data points and the center position, the farthest position of the fault data point and the average position of the fault data point;
a wavelet basis function determining module configured to determine an optimal wavelet basis function for extracting the fault features of the analog circuit according to the score.

9. The system according to claim 6, wherein the calculation module is configured to obtain the center positions of the respective faults based on
$${Mean}_{j , k} = \frac{1}{N} {\sum }_{i = 1}^{N} {P}_{j , k , i} ,$$
obtain the distance between the respective fault data points and the center position based on O_{j,k,i}=Distance(Mean_{j,k}, P_{j,k,i}), obtain the farthest position of the fault data point based on max O_{j,k}=arg max{O_{j,k,i}}, and obtain the average position of the fault data point based on
$$m e a n {O}_{j , k} = \frac{1}{N} {\sum }_{i = 1}^{N} {O}_{j , k , i} ,$$
wherein j=1 . . . J, J is the number of the wavelet basis functions; k=1 . . . K, K is the number of faults; i=1 . . . N, N is the number of the data points for a single fault; P_{j,k,i} is a coordinate position of the i-th data point of the k-th fault in the feature extracted based on the j-th wavelet basis function, Distance is an Euclidean distance calculation function, and O_{j,k,i} is a distance between the i-th data point P_{j,k,i} of the k-th fault in the feature extracted based on the j-th wavelet basis function and the center position Mean_{j,k}.

10. The system according to claim 7, wherein the feature score discriminating module is configured to obtain the score of the feature extracted based on the j-th wavelet basis function based on
$${Score}_{j} = {\sum }_{m = 1}^{C ( K , 2 )} {Judge}_{j , m} ,$$
wherein m=1 . . . C(K, 2), which is the m-th combination of two faults among the K types of faults, and Judge_{j,m} is a score of m-th combination of two faults, and
$${Judge}_{j , m} = \\ \{ \begin{matrix}1 & Distance ( {Mean}_{j , {k}_{1}} , {Mean}_{j , {k}_{2}} ) \geq max {O}_{j , {k}_{1}} + max {O}_{j , {k}_{2}} \\ Distance ( {Mean}_{j , {k}_{1}} , {Mean}_{j , {k}_{2}} ) / max {O}_{j , {k}_{1}} + max {O}_{j , {k}_{2}} & Distance ( {Mean}_{j , {k}_{1}} , {Mean}_{j , {k}_{2}} ) < max {O}_{j , {k}_{1}} + max {O}_{j , {k}_{2}}\end{matrix} ,$$
wherein k₁, k₂ indicate two different faults.

11. The system according to claim 8, wherein the wavelet basis function determining module is configured to determine the wavelet basis function with the highest score based on Scoreₜ=arg max{Scoreⱼ}, if there is only one wavelet basis function satisfying the highest score, the wavelet basis function satisfying the highest score is used as the optimal wavelet basis function for extracting the fault features of the analog circuit;
if there are S types of wavelet basis functions satisfying the highest score, the s-th type of wavelet basis function among the S types of wavelet basis functions that satisfy
$${meanO}_{j , s} = argmin \{ {\sum }_{j = 1}^{J} {meanO}_{j , k} \}$$
is taken as the optimal wavelet basis function for extracting the fault features of the analog circuit.

12. The system according to claim 7, wherein the number of the wavelet basis functions is equal to the number of the features; the coordinate position of the i-th data point of the k-th fault in the feature extracted based on the j-th wavelet basis function is the value of the i-th data point of the k-th faults in the feature extracted based on the j-th wavelet basis function.

13. The system according to claim 8, wherein the number of the wavelet basis functions is equal to the number of the features; the coordinate position of the i-th data point of the k-th fault in the feature extracted based on the j-th wavelet basis function is the value of the i-th data point of the k-th faults in the feature extracted based on the j-th wavelet basis function.

14. The system according to claim 9, wherein the number of the wavelet basis functions is equal to the number of the features; the coordinate position of the i-th data point of the k-th fault in the feature extracted based on the j-th wavelet basis function is the value of the i-th data point of the k-th faults in the feature extracted based on the j-th wavelet basis function.
